(19) United States
(12) Patent Application Publication
(10) Pub. No.: US 2020/0386530 A1
(43) Pub. Date: Dec. 10, 2020

(54) Inductive Position and Velocity Estimator

(71) Applicant: David T. Starkey, La Jolla, CA (US)

(72) Inventor: David T. Starkey, La Jolla, CA (US)

(21) Appl. No.: 16/433,930

(22) Filed: Jun. 6, 2019

(51) Int. Cl. G01B 7/00; H03M 1/12; G01D 5/20

(52) U.S. Cl. CPC G01B 7/003; G01D 5/202; H03M 1/12

(57) ABSTRACT

A position sensor has a plurality of moveable surfaces, each moveable surface having a region with an electrically conductive surface. Each moveable surface has an inductor which forms a magnetic field inducing eddy currents in the electrically conductive surface. The inductor is momentarily connected to a pre-charged capacitor, thereby forming an LC resonant circuit, and disconnected before a quarter cycle of the LC resonant period occurs. The voltage on the capacitor is read at the end of the measurement period and before the next capacitor pre-charge event. As the eddy currents generated in the electrically conductive surface by the inductor cause a damping of the LC resonant waveform, the voltage at the end of the measurement cycle varies monotonically with the position of the moveable surface.

### FIELD OF THE INVENTION

The present invention relates generally to proximity detection and position estimation, with application to estimating key position and key velocity in a musical keyboard instrument. In particular, the invention relates to a proximity and separation distance measurement system and method using inductive and eddy current loss with applications for estimating key press displacement in musical instruments.

### BACKGROUND OF THE INVENTION

There are several types of key position estimators for musical keyboards. In one prior art system, mechanical actuators are connected to the keys of a keyboard, each mechanical actuator coupled to a graduated shutter attenuating the path of an optical beam through the shutter, and to a detector which estimates key position from the measured optical signal intensity. This system has the disadvantage of requiring one position estimator for each key. In another prior art system by the present inventor, each key has a bottom surface, opposite of which is an LED (light emitting diode) source and an optical detector. The LED optical source reflects optical energy from the bottom surface of an associated key and reflected optical energy returns to an associated optical detector. As reflected optical energy follows the inverse square law, the separation distance may be estimated from detected optical intensity, and the optical sources may be multiplexed with the detectors all wired in parallel to reduce the number of analog to digital converters (ADC) by grouping the detectors for several keys, and repeating this in groups to estimate the positions of each of the 88 keys on a standard piano keyboard. However, this system also has several disadvantages. One disadvantage is the need to compensate for cross-channel interference, whereby optical energy reflecting from adjacent key optical sources from the bottom surface of the key couples into the detector for an unrelated adjacent key. Another disadvantage is that each key may have a different reflectivity, requiring a calibration that may change as airborn particles accumulate on the reflective surface. Most significantly, the optical detectors of the system are sensitive to ambient lighting which leaks through the keys and to the detectors below.

An improved key estimation system is desired which is insensitive to the reflectivity of the keys, insensitive to ambient light leaking through the keys, and does not require the cross-channel calibration of the prior art.

### OBJECTS OF THE INVENTION

A first object of the invention is a capacitor in parallel with the series combination of an inductor in series with a current-inducing element such as a switch or current source, the inductor generating a magnetic field when energized which couples to a loss element generating eddy currents, the loss element positioned to generate eddy currents from the change in magnetic field generated by the inductor, the capacitor pre-charged to a charge voltage, closure of the switch resulting in a fraction of a cycle of natural resonant period of the capacitor and inductor, the switch thereafter opening, the voltage across the capacitor being read thereafter as an estimate of separation distance inferred from the inductive eddy current loss and change in inductance from the eddy current losses between the inductor and eddy current loss element, the capacitor voltage being linearized into an estimate of separation distance between the inductor and loss element.

In a second object of the invention, a series of estimates of separation distance between a substantially planar conductor and an inductor generating eddy currents in the substantially planar conductor are measured at the end of a quarter cycle of resonance and converted into Musical Instrument Digital Interface (MIDI) commands indicating at least one of a key velocity or position.

In a third object of the invention, a movable key of a musical instrument has a metallic tape on a surface facing an inductor, the metallic tape proximal to and substantially perpendicular to a magnetic field generated by an inductor, the inductor excited with a current which has at least one of a damping ratio or mutual inductance modified by eddy currents induced in the metal tape by current flowing in the inductor, the change in damping, mutual inductance, or eddy current loss periodically read as the voltage on a capacitor after the excitation current is initiated to form an estimate of separation distance between the inductor and the metallic tape.

In a fourth object of the invention, a movable surface has an electrically conductive loss element positioned on the moveable surface, the loss element coupled to a changing magnetic field generated by discharging a pre-charged capacitor into an inductor, thereby generating eddy currents in the loss element which are dependent on the separation distance between the inductor and loss element, the inductor and capacitor remaining connected for less than a quarter cycle of the natural resonance of the inductor and capacitor, the capacitor thereafter isolated from the inductor, the capacitor voltage measured at the end of a fixed interval, the voltage on the capacitor at the end of the interval linearized and forming an estimate of the separation distance between the inductor and the loss element.

### SUMMARY OF THE INVENTION

In a first aspect of the invention, a keyboard musical instrument has a movable surface with a loss element, such as an electrically conductive material applied to a region of the movable surface, which is in proximity to an inductor in a fixed position with respect to the moveable surface, the separation distance from inductor to loss element (such as an electrically conductive surface) and inductor magnetic field sufficient to induce eddy currents from changes in current flow in the inductor magnetic field which is coupled to the conductive loss element material based on separation distance. The magnetic fields coupled between the movable conductive loss element material and fixed inductor generating the dynamic magnetic field are modified by eddy currents induced in the conductive loss element material, and also by the separation distance from the inductor to the loss element. An estimate of the separation distance may be formed from the effect of the eddy current losses to the inductor, as measured by a capacitor voltage coupled to the inductor during the pulsatile current at a fixed point in time after initiation of current flow in the inductor.

In one example of the invention, a capacitor is pre-charged to a charge voltage, the capacitor being in parallel with a series combination of an inductor and a switch element such as a field effect transistor (FET) or controllable current source. The inductor is configured to generate a magnetic field which induces eddy currents in a loss element such as a planar conductor positioned substantially perpendicular to the inductor central axis, the planar conductor positioned on a surface of the moveable key which moves with respect to the fixed position inductor. The measurement switch causes the capacitor to discharge into the inductor, and a current to flow in the inductor which is now in a resonant circuit with the capacitor. Before the end of a first cycle of the inductor/capacitor resonant circuit, the measurement switch opens, thereby freezing the capacitor voltage for subsequent reading by an analog to digital converter. In one example of the invention, the measurement switch opens before ¼ of an LC resonant cycle interval. The eddy currents induced in a loss element such as a planar conductor coupled to the inductor across a variable separation distance causes a quarter cycle of damped ringing, which results in a reduced amplitude at the end of the quarter cycle measurement interval. Due to the change in damping factor and mutual inductance from the inductor coupling to the negligible inductance of the loss element, the capacitor voltage at the end of the measurement interval is reduced with decreased separation distance between inductor and loss element, thereby providing a non-linear estimate of separation distance from the inductor to planar conductor. The capacitor voltage at the point of opening the current initiating element can then be read by the analog to digital converter, linearized, and provided as an estimate of key position or separation distance from inductor to conductive loss element such as aluminum or copper tape oriented substantially perpendicular to the winding axis of the inductor.

In another aspect of the invention, a single capacitor is pre-charged by a single pre-charge switch element, the single capacitor being in parallel with a plurality of inductor/switch elements, each inductor/switch operative to form eddy currents in combination with a planar conductor for each movable surface such as a key of a keyboard. In this manner, a single ADC may be used to read the capacitor voltage for a group of keys, each key having its separate inductor/switch actuated at a separate interval of time, each separate interval preceded by a capacitor pre-charging event, thereby reducing the ADC requirement to one per group of keys, each key having a separate measurement switch actuation control.

### BRIEF DESCRIPTION OF THE DRAWINGS

FIG. 1A is a schematic diagram of a circuit for estimation of separation distance from an inductor to a planar conductor using a controllable current source.

FIG. 1B is a schematic diagram of a circuit for estimation of separation distance from an inductor to a planar conductor using a switch element.

FIG. 2 shows the waveforms for operation of the separation distance estimator of FIG. 1B performing a series of measurements.

FIG. 3 shows a detailed view of waveforms for a single measurement event for FIG. 1B using the waveforms of FIG. 2.

FIG. 4 shows a block diagram for a multiplexed measurement architecture using a single capacitor and ADC for estimating the position of a group of keys.

FIG. 5 shows a timing diagram with waveforms for FIG. 4.

FIG. 6A shows a cross section view of a key in a rest position.

FIG. 6B shows the key of FIG. 6A in a pressed position.

### DETAILED DESCRIPTION OF THE INVENTION

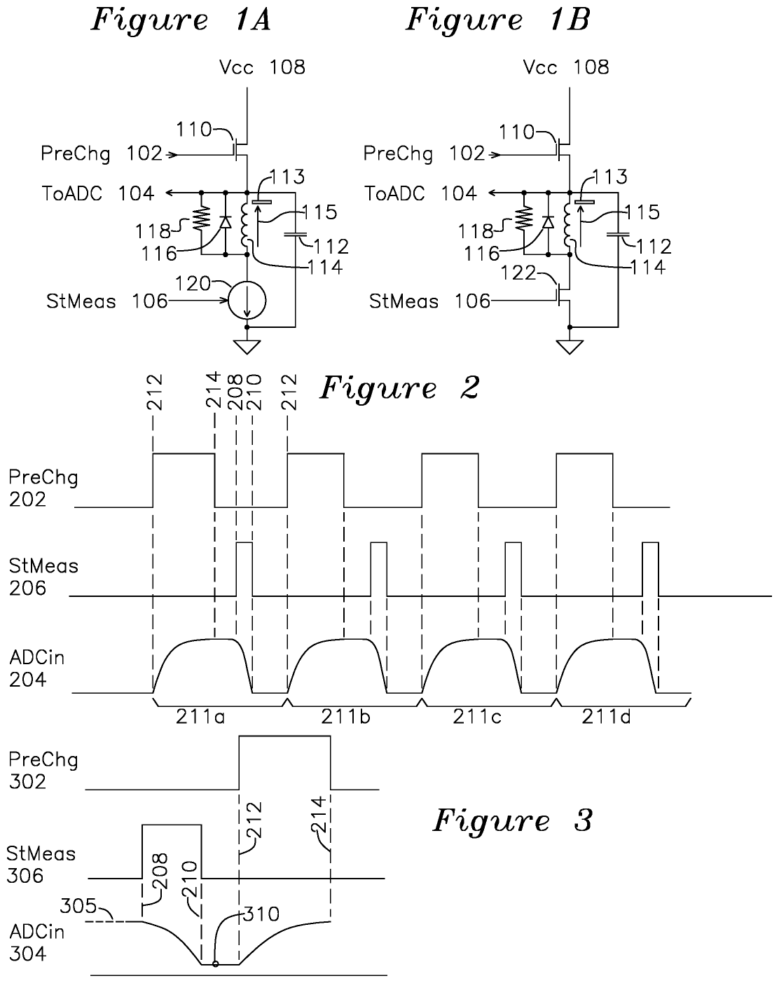

FIG. 1A shows a first example of an estimator for separation distance between an inductor 114 and a moveable loss element 113 such as a planar conductor oriented substantially perpendicular to the magnetic field generated by inductor 114 based on separation distance from the loss element 113 to inductor 114. The moveable loss element 113 induces varying levels of eddy currents from the magnetic field generated by inductor 114. In a first step of operation, precharge control 102 is asserted to switch element 110 which is shown as a field effect transistor (FET), which charges capacitor 112 to an initial voltage such as VCC 108, during which interval Start Measurement (StMeas 106) signal is not enabled, and current source 120 is not operative, such that no current flows in inductor 114 while capacitor 112 charges.

In a second step of operation, Precharge signal 102 is disabled by turning off switch element 110, and StMeas 106 is asserted, which initiates a current flow in inductor 114, which is now in an LC resonant circuit with capacitor 112. A damped sinusoidal current flow through inductor 114 begins, and prior to the end of a quarter cycle of resonant period of the LC circuit, StMeas 106 is de-asserted, and current flowing through inductor 114 is returned via clamp diode 116 until the current in inductor 114 dissipates. A decrease in separation distance between inductor 114 magnetic field and loss element 113 causes an increase in the damping of the LC circuit as well as a decrease in the inductance and increase in resonant frequency from the mutual inductance effect from coupling to the miniscule inductance of loss element 113, which causes a reduced capacitor voltage 112 at the end of an interval which is less than a quarter cycle of an LC resonant frequency. An increase in separation distance between inductor 114 magnetic field and loss element 113 causes a decrease in the damping of the LC circuit as well as the inductor to return to a value closer to its self-inductance, and an increased capacitor 112 voltage at the end of the measurement interval. After removal of StMeas 106 and opening of current source 120, the capacitor 112 voltage is frozen in its previous state of the LC resonant cycle, and the capacitor 112 voltage ToADC 104 may be read at any any time thereafter prior to the start of the next measurement cycle, such as by coupling to an ADC (analog to digital converter, not shown). Each measurement cycle repeats at regular intervals, each measurement of voltage at capacitor 112 being converted to a voltage read by an ADC, linearized according to the monotonic relationship which can be formed between capacitor 112 voltage at end of cycle associated with a separation distance from inductor 114 to loss element 113.

The inductor 114 L value and capacitor C 112 form a damped resonant circuit with a cycle time 1/2π\sqrt{LC}, where L is the effective inductance of 114 which including self-inductance and mutual inductance to loss element 113 which has negligible inductance. The mutual inductance which reduces the inductance of L is dependent on separation distance and dynamic flux coupling from the inductor 114 to loss element 113, and the pre-charge applied to capacitor 112 starts the damped resonance cycle with the closure of switch 120 of FIG. 1A or switch 122 of FIG. 1B.

FIG. 1B shows a preferred variation to the circuit schematic of FIG. 1A, where current source 120 with external enable input 106 is replaced by a switch such as FET 122. In the present specification, similarly numbered elements represent the same element in other figures.

FIG. 2 shows example waveforms for the operation of the circuit of FIG. 1B (also similar to the operation of FIG. 1A). Capacitor 112 is precharged by assertion of Precharge 202 signal shown as input 102 of FIG. 1B. The duration of the precharge interval 212 to 214 is chosen to be sufficient to enable capacitor 112 to fully charge, as shown by waveform 204 ADCin from 212 to 214, which is also the voltage of capacitor 112. After the precharge interval from 212 to 214, StMeas 106 is asserted as shown in waveform 206, which closes switch 122 and forms an LC resonant circuit between capacitor 112 and inductor 114, and the rapidly changing current in inductor 114 causes eddy currents to form in loss element 113. The greater the eddy current loss, the less voltage that is present at time 210 because of the decreased inductance and magnetic flux loss in loss element 113 causing damping when StMeas 206 is unasserted and switch 122 opens, freezing the capacitor voltage to its previous value. Optional clamp diode 116 absorbs current which flows in inductor 116 at the moment switch 122 opens, to re-initialize the inductor for a subsequent cycle and provide overvoltage protection for FET 122 if necessary. Optional resistor 118 provides damping to reduce the Q of the LC circuit in combination with the eddy currents generated in movable loss element 113, if needed.

FIG. 3 shows detailed waveform plots for the operation of FIG. 1B, where the capacitor voltage at ADCin 304 is pre-charged to fixed level 305 by a previous pre-charge cycle, followed by StMeas from interval 208 to 210, at the end of which the ADCin 304 is stable, and the ADC samples 310 the capacitor 112 voltage at any time from time interval 210 to 212 in a repetitive cycle 211a, 211b, 211c, 211d as shown in FIG. 2.

The relationship between capacitor voltage 204 at the end of the measurement cycle and the separation distance between loss element and inductor is monotonic, but may be non-linear, whereas the desired estimate is of a separation distance between loss element and the inductor. For this reason, it may be desirable to linearize the ADC readings 310 of the capacitor voltage 204 using a look-up table of correspondences, or a second order or higher equation which curve fits the capacitor voltage to estimates of separation distance. Additionally, it may be desirable to use adjacent time sequence samples of the estimated separation distance to form a moveable surface velocity, such as for sending data related to key position and velocity in the Musical Instrument Data Interface (MIDI) format. In another example of the invention for a musical instrument having keys in a rest position and a depressed position, a calibration sequence may be performed to associate a first calibration value with a moveable surface rest measurement and a second calibration value with a moveable surface depressed position, thereby providing endpoints for a range of separation distance estimates and capacitor voltage samples. The first and second calibration values may be used in conjunction with the capacitor voltages which are read at the end of the StMeas interval, and used to scale the capacitor ADC voltage to form a scaled value for application to a linearizing function using a look-up table or polynomial of second or greater order.

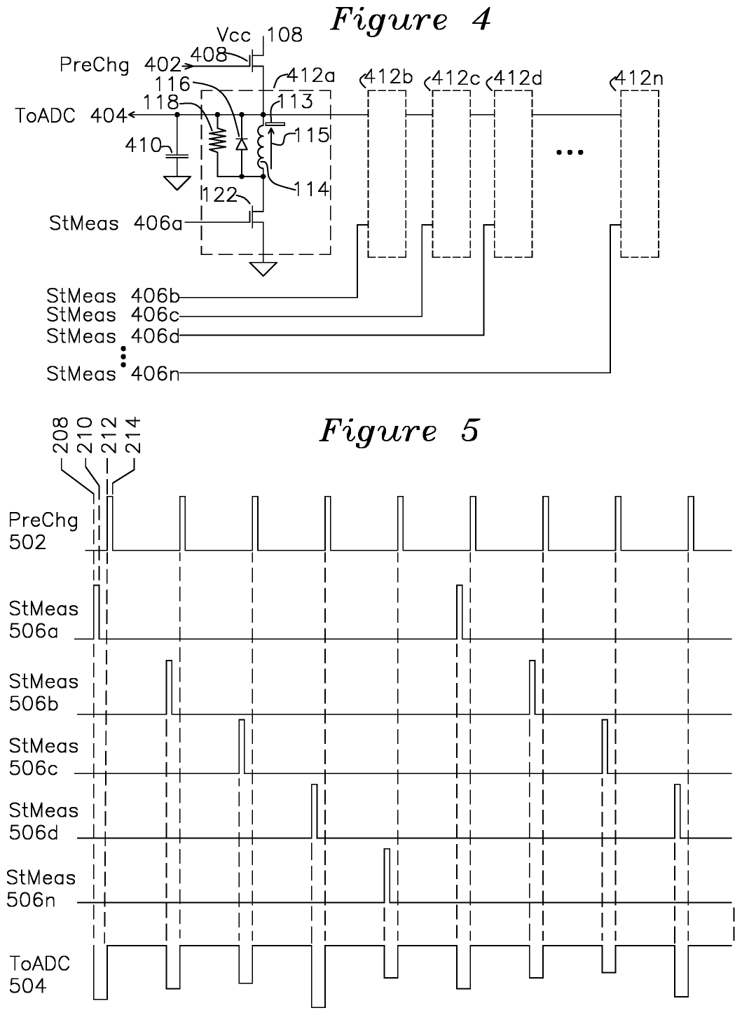

FIG. 4 shows a multiplexed embodiment of the position estimator of FIG. 1B, where a single precharge switch 408 pre-charges capacitor 410, and separate measurement circuits 412a, 412b, 412c, 412d, . . . , 412n all are commonly connected to capacitor 410, and each measurement circuit has a separate StMeas input 406a, 406b, 406c, 406d, . . . , 406n, and the circuitry shown in 412a is operative as was shown for single measurement circuit of FIG. 1B with the exception of shared precharge switch 408 and shared capacitor 410 for each module of FIG. 4. In one example of the invention, each measurement cycle such as 211a is on the order of 200 us, and the earlier group of 16 estimators 412-1 to 412-16 of FIG. 4 samples each of the position estimators every 3.2 ms in this example in the canonical sequence.

FIG. 5 shows the waveforms of operation for FIG. 4, with precharge waveform 502 applied to 402 of FIG. 4, and common ToADC 404 shown as waveform 504. Each measurement circuit 412a, 412b, 412c, 412d, . . . , 412n has a corresponding StMeas waveform 506a, 506b, 506c, 506d, . . . , 506n which are enabled in a repeating canonical sequence as shown. In this manner, a single analog to digital converter (ADC) may be coupled to waveform 504, and each of the key positions read in sequence using each associated measurement circuit.

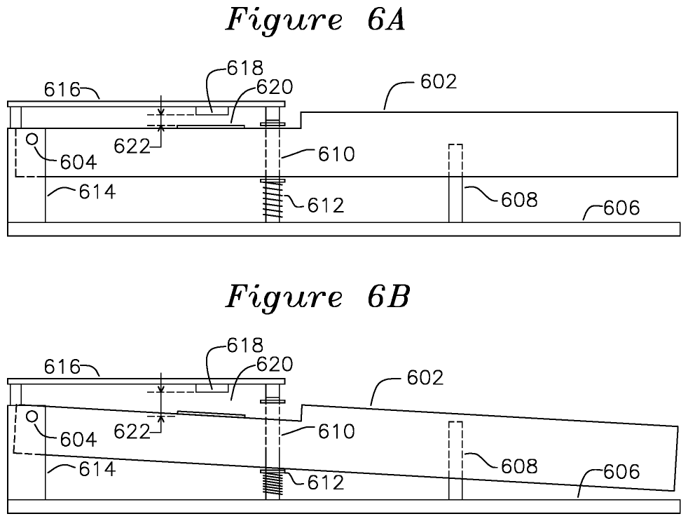

Although the invention may be generally practiced to estimate distance between a movable surface and an inductor, FIGS. 6A and 6B show a particular example of the invention for use with a keyboard, showing a single key in the FIG. 6A rest position, and the same key in FIG. 6B in a depressed position. Piano key 602 is operative to rotate about a pivot 604 on support 614 to substrate 606, which also supports an end of travel stop 608 which is positioned in a blind slot in the underside of key 602. A second post 610 travels through the key 602 and is mounted to substrate 606 and includes spring 612 which returns the key 602 to the rest position shown in FIG. 6A, as well as reducing lateral movement of the key 602. Although the location is arbitrary, FIG. 6A shows a circuit board 616 which is in a fixed position with respect to the moving key 602, such as secured to second post 610 with respect to substrate 606, where circuit board 616 includes inductor 618 corresponding to inductor 114 of FIG. 1B, where the other components of FIG. 1B may be mounted to circuit board 616, and loss element 113 affixed to the movable key 602 as 620. FIG. 6B shows the key of FIG. 6A in the depressed state, with the separation distance 622 from inductor 618 to loss element 620 increased in FIG. 6B compared to FIG. 6A, resulting in less eddy current losses coupled to the inductor 618.

In a preferred example, inductor 618 generates a magnetic field which is substantially perpendicular to the conductive plane of loss element 618, where substantially perpendicular is understood to be within 45 degrees of perpendicular, or any angle which couples a magnetic field generated by inductor 618 into eddy current losses. It is known from Lenz law that eddy current losses are present in any electrical conductor placed perpendicular to a changing magnetic field such as produced by inductor 618. Accordingly, in a preferred example of the invention, inductor 618 does not include an enclosed magnetic return path, such that the magnetic field is directed toward loss element 620. Loss element 620 can be a conductive metal containing at least one of: copper, aluminum, or other electrical conductor, preferably as a continuous planar conductor spanning a region of key 602 magnetically coupled to, and substantially perpendicular to the axis of, inductor 618. The conductive metal can be attached to key 602 using an adhesive, or any other suitable attachment means.

In one example of the invention, an 88 key piano utilizes 5 groups of 16 circuits (such as 412-1 to 412-16) and a group of 8 circuits (412-1 to 412-8), requiring only 6 ADC channels (one for each group). The group of 8 circuits may sample at double the rate of the groups of 16 circuits, or it may preferably sample at the same rate for consistency. In another example of the invention, 8 groups of 11 circuits (412-1 to 412-11) may be used for 88 keys, requiring 8 ADC inputs.

The loss element magnetically coupled to the changing fields of the inductor may include any conductive surface which is coupled to the magnetic field of a respective inductor for generation of eddy currents. For example, the loss element can be a metallic tape such as copper or aluminum with self-adhesive backing. It is preferable that the axis of the inductor be substantially perpendicular to the surface of the loss element for maximum coupling.

The loss element may take the form of a planar conductor which may be any thickness or shape sufficient to generate eddy currents from pulsatile current flow in an inductor magnetically coupled to the loss element. In a preferred embodiment, the loss element is aluminum self-adhesive tape, and in an example such as 620 of FIGS. 6A and 6B, may be attached to the moveable surface 602 piano key opposite the inductor 618. The example is for illustration only, it is understood that the inductor 618 and loss element 620 may be positioned opposite each other on a top or bottom surface of key 602.

The present examples are provided for illustrative purposes only, and are not intended to limit the invention to only the embodiments shown.

We claim:

1) A position estimator comprising:
a loss element attached to the moveable surface;
an inductor positioned to generate a dynamic magnetic field causing eddy currents in the loss element, a separation distance between loss element and inductor changing when the moveable surface changes position;
a charged capacitor coupled to a switch to generate a current flow in the inductor for a duration of time less than a quarter cycle of the resonant frequency of the inductor and capacitor circuit, thereafter opening the switch;
the voltage present on the capacitor read by an analog to digital converter (ADC) and converted to an estimate of the separation distance between the inductor and loss element.

2) The position estimator of claim 1 where the loss element is a substantially planar electrical conductor.

3) The position estimator of claim 2 where the planar electrical conductor includes at least one of copper or aluminum.

4) The position estimator of claim 1 where the capacitor is periodically pre-charged at the beginning of a cycle, after which the switch is closed for a second interval of time and then opened, and the capacitor is read after the second interval of time and before a subsequent pre-charge event.

5) The position estimator of claim 1 where the moveable surface is a key having a pivot, and the loss element is electrically conductive tape attached to the key.

6) The position estimator of claim 1 where the conversion to an estimate of separation distance includes a first calibration value associated with a first separation distance and a second calibration value associated with a second separation distance.

7) The position estimator of claim 6 where the moveable surface is a key of a musical instrument, and the first calibration value is associated with a key rest position and the second calibration value is associated with a key depressed position.

8) A sensor for estimating the separation distance between a movable surface having a conductive loss element and an inductor which generates eddy currents in the loss element, the sensor comprising:
the movable surface having a pivot and a return-to-rest mechanism such that the distance between the loss element and the inductor changes when the movable surface is displaced from a rest position;
a pre-charged capacitor in parallel with the inductor and a switch;
the switch closed for a duration of time less than a quarter cycle of the resonant frequency of the inductor and capacitor;
the capacitor voltage read after the switch is opened to form an estimate of separation distance between the loss element and the inductor.

9) The sensor of claim 8 where the estimate of separation distance is formed by applying the capacitor voltage read after the switch is opened to at least one of: a look-up table or a second order or greater equation.

10) The sensor of claim 8 where the pre-charging of the capacitor, closing of the switch for the duration of time, and the capacitor voltage being read occur in a series of canonical cycles, thereby providing a moveable surface position and also a velocity.

11) The sensor of claim 8 where the movable surface is a key for a musical instrument, and the loss element includes an electrically conductive surface including at least one of aluminum or copper.

12) The sensor of claim 11 where the moveable surface has a rest position and an associated first calibration value associated with a capacitor ADC reading at the rest position, and the movable surface has a depressed position and an associated second calibration value associated with a capacitor ADC reading at the depressed position.

13) The sensor of claim 12 where the capacitor ADC reading is scaled using the first calibration value and second calibration value prior to being linearized to a separation distance estimate, the linearized value using at least one of a lookup table or a second order or higher order polynomial.

14) A multiplexed movable surface sensor for a plurality of movable surfaces comprising:
a capacitor coupled to a pre-charge switch charging the capacitor to a charge voltage at the start of a series of canonical cycles;
a plurality of movable surfaces, each moveable surface having a loss element magnetically coupled to an associated inductor generating a dynamic magnetic field sufficient to generate eddy currents in the associated loss element;
one end of each associated inductor coupled to the capacitor receiving the charge voltage, the other end of each associated inductor connected to a measurement switch;
each canonical cycle comprising:
closing the pre-charge switch until the capacitor is charged;
closing a measurement switch for an associated subsequent inductor for a measurement interval of time;
opening the measurement switch;
reading the capacitor voltage and converting the capacitor voltage to an estimate of separation distance from the inductor to the loss element.

15) The multiplexed moveable surface sensor of claim 14 where converting the capacitor voltage to a movable key displacement includes a comparison with one or more previous separation distance estimates to estimate a moveable key velocity.

16) The multiplexed moveable surface sensor of claim 14 where the plurality of moveable surfaces comprise a plurality of keyboard keys, each key having an associated loss element coupled to an associated inductor.

17) The multiplexed moveable surface sensor of claim 14 where the plurality of moveable surfaces comprise a plurality of keyboard keys, each key having an associated rest and depressed calibration value used in forming an associated conversion of capacitor voltage to an associated separation distance.

18) A method for estimating a moveable surface, the moveable surface having a region generating eddy currents when coupled to an inductor generating a dynamic magnetic field, such that the separation distance between the planar conductor and inductor changes monotonically when the separation distance from the inductor to the region generating eddy currents is changed, the method comprising:
pre-charging a capacitor to a charge voltage;
connecting the capacitor to the inductor for a measurement duration of time which is shorter than a quarter cycle of the frequency of the inductor/capacitor combination;
removing the connection between the capacitor and inductor;
reading the voltage on the capacitor;
converting the capacitor voltage to an estimate of the separation distance.

19) The method of claim 18 where the moveable surface is a key of a musical instrument having a rest position and a depressed position, and the capacitor voltage associated with the rest position has a first calibration value and the capacitor voltage associated with the depressed position has a second calibration value, the first and second calibration values used to form a scaled estimate.

20) The method of claim 19 where the scaled estimate is converted to a separation distance measurement using at least one of a look-up table or a second order or higher order polynomial.
